(19) United States
(12) Patent Application Publication
(10) Pub. No.: US 2014/0191369 A1
(43) Pub. Date: Jul. 10, 2014

(54) NITRIDE SEMICONDUTOR DEVICE

(71) Applicant: Hitachi Metals, Ltd., Tokyo (JP)

(72) Inventors: Tadayoshi TSUCHIYA, Hitachi (JP); Naoki KANEDA, Hitachi (JP); Tomoyoshi MISHIMA, Hitachi (JP)

(73) Assignee: Hitachi Metals, Ltd., Tokyo (JP)

(21) Appl. No.: 14/068,067

(22) Filed: Oct. 31, 2013

(30) Foreign Application Priority Data
Jan. 8, 2013 (JP) 2013-001046

(51) Int. Cl. H01L 21/02; H01L 29/20

(52) U.S. Cl. CPC H01L 21/02617; H01L 21/0254; H01L 29/2003
USPC 257/615

(57) ABSTRACT

A nitride semiconductor device includes a first nitride semiconductor layer, and an npn junction structure including a second nitride semiconductor layer of an n-type conductivity, a third nitride semiconductor layer of a p-type conductivity, and a fourth nitride semiconductor layer of an n-type conductivity layered in this order on the first nitride semiconductor layer. The third nitride semiconductor layer includes two or more uncovered regions which are uncovered with the fourth nitride semiconductor layer.

The present application is based on Japanese patent application No. 2013-001046 filed on Jan. 8, 2013, the entire contents of which are incorporated herein by reference.

### BACKGROUND OF THE INVENTION

1. Field of the Invention

The invention relates to a nitride semiconductor device.

2. Description of the Related Art

Gallium nitride is suitable for a semiconductor material for a high output transistor, because the gallium nitride has a wider band gap, larger breakdown field strength, and is excellent in heat resistance, as compared with silicon. However, when manufacturing an npn junction type semiconductor device using a gallium nitride-based semiconductor, the activation rate of acceptors in p-type layers is poor, so that it is difficult to achieve good characteristics. As one of the causes of the poor activation rate, the inactivation mechanism of the acceptors due to hydrogen atoms has been pointed out by W. Gotz, et al., Appl. Phys. Lett., 67, 2666(1995).

As the film formation method of semiconductor layers in a semiconductor device made of a nitride semiconductor, Metal-Organic Vapor Phase Epitaxy (MOVPE) method and Hydride Vapor Phase Epitaxy (HVPE) method have been generally used. During deposition by these methods, hydrogen is incorporated into the semiconductor layer. As the film formation method by which hydrogen will not be mixed into the semiconductor layer, molecular beam epitaxy method or the like has been studied. However, good crystal properties cannot be obtained yet by such method, so that MOVPE method or the HVPE method is still used.

To solve the aforementioned problems and thereby activate the acceptors in the p-type semiconductor layer in the npn junction type semiconductor device made of the nitride semiconductor, a technique of dissociating a bond between the acceptor and hydrogen by heat treatment to release hydrogen has been known, as disclosed by JP-A-2003-60222.

### SUMMARY OF THE INVENTION

However, in the npn junction type semiconductor device disclosed by JP-A-2003-60222, hydrogen in the p-type semiconductor layer is emitted from only a small exposed portion of the p-type semiconductor layer, since most of an upper surface of the p-type semiconductor layer is covered with an n-type semiconductor layer. Hydrogen remains in a region distant from the exposed portion of the p-type semiconductor layer and the acceptors therein are inactivated, so that it is impossible to achieve sufficient electrical conductivity throughout the p-type semiconductor layer.

Accordingly, it is an object of the invention to provide an npn junction type nitride semiconductor device with a p-type semiconductor layer, which has a sufficient electrical conductivity through an entire device.

According to a feature of the invention, a nitride semiconductor device comprises:

a first nitride semiconductor layer; and

an npn junction structure comprising a second nitride semiconductor layer comprising an n-type conductivity, a third nitride semiconductor layer comprising a p-type conductivity, and a fourth nitride semiconductor layer comprising an n-type conductivity layered in this order on the first nitride semiconductor layer,

in which the third nitride semiconductor layer comprises two or more uncovered regions which are uncovered with the fourth nitride semiconductor layer.

A shortest distance from an arbitrary point of a covered region which is covered with the fourth nitride semiconductor layer to the uncovered regions in the third nitride semiconductor layer is preferably 50 μm or less.

It is preferable that at least a portion of the uncovered regions is a region formed by a void portion opened at an upper surface of the fourth nitride semiconductor layer, and the fourth nitride semiconductor layer and the third nitride semiconductor layer constitute an inner side surface of the void portion.

The fourth nitride semiconductor layer, the third nitride semiconductor layer, and the second nitride semiconductor layer may constitute the inner side surface of the void portion.

It is preferable that at least a portion of the uncovered regions is a region exposed by a void portion opened at an upper surface of the fourth nitride semiconductor layer, the fourth nitride semiconductor layer comprises a plurality of portions divided by the void portion, a single electrode is connected to the plurality of portions in common, and the electrode is electrically insulated from the third nitride semiconductor layer by an insulating film formed inside the void portion.

The insulating film may comprise an insulating material composed mainly of silicon dioxide.

Each of the first nitride semiconductor layer, the second nitride semiconductor layer, the third nitride semiconductor layer, and the fourth nitride semiconductor layer may comprise a nitride semiconductor film formed by Material-Organic Vapor Phase Epitaxy or Hydride Vapor Phase Epitaxy.

### Effects of the Invention

According to the invention, it is possible to provide an npn junction type nitride semiconductor device with a p-type semiconductor layer, which has a sufficient electrical conductivity throughout an entire device.

### BRIEF DESCRIPTION OF THE DRAWINGS

Next, the present invention will be explained in more detail in conjunction with appended drawings, wherein:

FIGS. 1A to 1C are diagrams showing a nitride semiconductor device in the first embodiment according to the invention, wherein FIG. 1A is a vertical cross-sectional view thereof, FIG. 1B is a top view thereof, and FIG. 1C is a plan view showing a covered region and uncovered regions in a p-type nitride semiconductor layer thereof;

FIG. 2A and FIG. 2B are diagrams showing a modification example of the nitride semiconductor device in the first embodiment, wherein FIG. 2A is a top view thereof and FIG. 2B is a plan view showing a covered region and uncovered regions in a p-type nitride semiconductor layer thereof;

FIG. 3A and FIG. 3B are diagrams showing another modification example of the nitride semiconductor device in the first embodiment, wherein FIG. 3A is a top view thereof, and FIG. 3B is a plan view showing a covered region and uncovered regions in a p-type nitride semiconductor layer thereof;

FIG. 4A and FIG. 4B are diagrams showing still another modification example of the nitride semiconductor device in the first embodiment, wherein FIG. 4A is a top view thereof, and FIG. 4B is a plan view showing a covered region and uncovered regions in a p-type nitride semiconductor layer thereof;

FIG. 5A and FIG. 5B are diagrams showing a further modification example of the nitride semiconductor device in the first embodiment, wherein FIG. 5A is a top view thereof, and FIG. 5B is a plan view showing a covered region and uncovered regions in a p-type nitride semiconductor layer thereof;

FIGS. 6A to 6C are vertical cross-sectional views showing a process of manufacturing the nitride semiconductor device in the first embodiment;

FIGS. 7A and 7B are vertical cross-sectional views showing a modification example of the process of manufacturing the nitride semiconductor device in the first embodiment;

FIGS. 8A to 8C are diagrams showing a nitride semiconductor device in the second embodiment, according to the invention, wherein FIG. 8A is a vertical cross-sectional view thereof, FIG. 8B is a top view thereof, and FIG. 8C is a plan view showing a covered region and uncovered regions in a p-type nitride semiconductor layer thereof;

FIGS. 9A to 9D are vertical cross-sectional views showing a process of manufacturing the nitride semiconductor device in the second embodiment; and

FIG. 10 is a graph showing a relationship between a distance L and a residual hydrogen concentration after heat treatment in each sample according to Example.

### DETAILED DESCRIPTION OF THE PREFERRED EMBODIMENTS

### Summary of the Embodiment

An embodiment of the invention provides a nitride semiconductor device comprising a first nitride semiconductor layer; and an npn junction structure comprising a second nitride semiconductor layer comprising an n-type conductivity, a third nitride semiconductor layer comprising a p-type conductivity, and a fourth nitride semiconductor layer comprising an n-type conductivity layered in this order on the first nitride semiconductor layer, wherein the third nitride semiconductor layer comprises two or more uncovered regions which are uncovered with, i.e. exposed from the fourth nitride semiconductor layer.

According to the nitride semiconductor device, it is possible to effectively release hydrogen contained in the p-type nitride semiconductor layer by heat treatment. Therefore, it is possible to activate the acceptors and thereby suppress a decrease in electrical conductivity of the p-type nitride semiconductor layer due to hydrogen.

In addition, by forming the uncovered regions in an arrangement suitable to release hydrogen effectively, it is possible to activate the acceptors more effectively.

### First Embodiment

(Nitride Semiconductor Device)

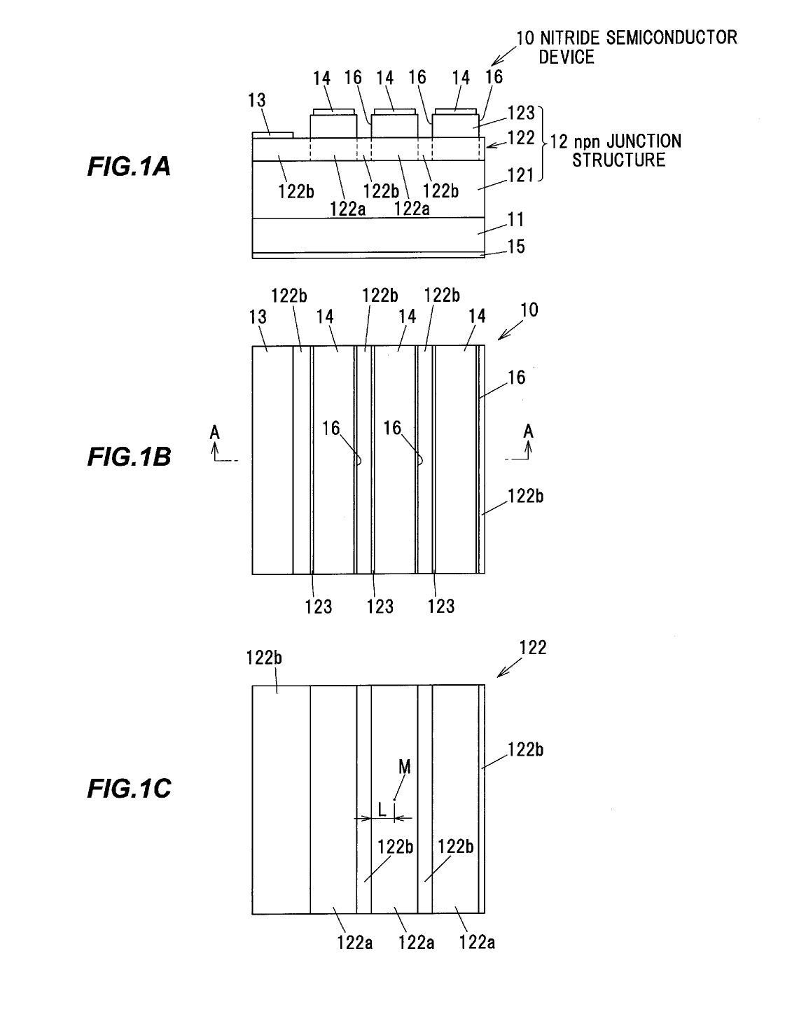

FIGS. 1A and 1B are diagrams showing a nitride semiconductor device in the first embodiment according to the invention, wherein FIG. 1A is a vertical cross-sectional view thereof, and FIG. 1B is a top view thereof. FIG. 1A is illustrating a cross-sectional view taken along line A-A in FIG. 1B.

A nitride semiconductor device 10 comprises an n-type nitride semiconductor layer 11, an npn junction structure 12 formed by laminating an n-type nitride semiconductor layer 121, a p-type nitride semiconductor layer 122, and an n-type nitride semiconductor layer 123 sequentially in this order on the n-type nitride semiconductor layer 11, an electrode 13 which is a base electrode electrically connected to the p-type nitride semiconductor layer 122, an electrode 14 which is an emitter electrode electrically connected to the n-type nitride semiconductor layer 123, and an electrode 15 which is a collector electrode electrically connected to the n-type nitride semiconductor layer 11.

The n-type nitride semiconductor layer 11, the n-type nitride semiconductor layer 121, the p-type nitride semiconductor layer 122, and the n-type nitride semiconductor layer 123 are nitride semiconductor films made of nitride semiconductor, i.e. AlₓGa_{y}In_{z}N (x+y+z=1, and 0≦x, y, z≦1), and are formed by MOVPE method or HVPE method.

In the case of forming the nitride semiconductor film by MOVPE method or HVPE method, hydrogen is taken into the formed film. Then, hydrogen taken into a p-type nitride semiconductor layer is bonded to an acceptor (a p-type impurity), and inactivates the acceptor. The inactivated acceptor loses its function as the acceptor, so the electrical conductivity of the p-type nitride semiconductor layer is deteriorated.

In the nitride semiconductor device 10 according to the present embodiment, two or more uncovered regions 122b are uncovered with, i.e. exposed from the n-type nitride semiconductor layer 123 in the p-type nitride semiconductor layer 122, so that the number of discharging paths for hydrogen is greater as compared with the conventional structure. Therefore, it is possible to effectively release hydrogen inside the p-type nitride semiconductor layer 122 and to activate the acceptors, so that the decrease in electrical conductivity of the p-type nitride semiconductor layer 122 due to hydrogen is suppressed.

The n-type nitride semiconductor layer 123 as shown in FIGS. 1A and 1B is divided into a plurality of portions by a void portion 16 which is a groove. The uncovered regions 122b that are uncovered with the n-type nitride semiconductor layer 123 in the p-type nitride semiconductor layer 122 comprise a region for electrically connecting the electrode 13, and a region formed by the void portion 16 which is opened at an upper surface of the n-type nitride semiconductor layer 123.

In the p-type nitride semiconductor layer 122, the shortest distance from an arbitrary point of a covered region 122a which is covered with the n-type nitride semiconductor layer 123 to the uncovered region(s) 122b which is uncovered with the n-type nitride semiconductor layer 123 is 50 μm or less. In other words, if hydrogen in any position inside the covered region 122a moves for 50μm at maximum in a straight line in the p-type nitride semiconductor layer 122, it will be discharged to the outside from an upper surface of the uncovered region(s) 122b. If this condition is satisfied, it is possible to effectively release hydrogen in the p-type nitride semiconductor layer 122 by heat treatment. An opening area of each void portion 16 is not particularly limited. Even if the opening area has the minimum size which can be formed by the lithography, etc., it will be possible to release hydrogen without any problem.

FIG. 1C is a plan view showing the covered region 122a and the uncovered regions 122b in the p-type nitride semiconductor layer 122. A point M in FIG. 1C is one of the farthest points in the covered region 122a from the uncovered region(s) 122b and the most hydrogen-remaining point after heat treatment. As will be described later, it is possible to measure a hydrogen concentration in the point M, and to use the measured value as an indicator of the rate of hydrogen removal effect by heat treatment.

The distance L in FIG. 1C represents the shortest distance from the point M to the uncovered region(s) 122b, and the distance L is not greater than 50 μm.

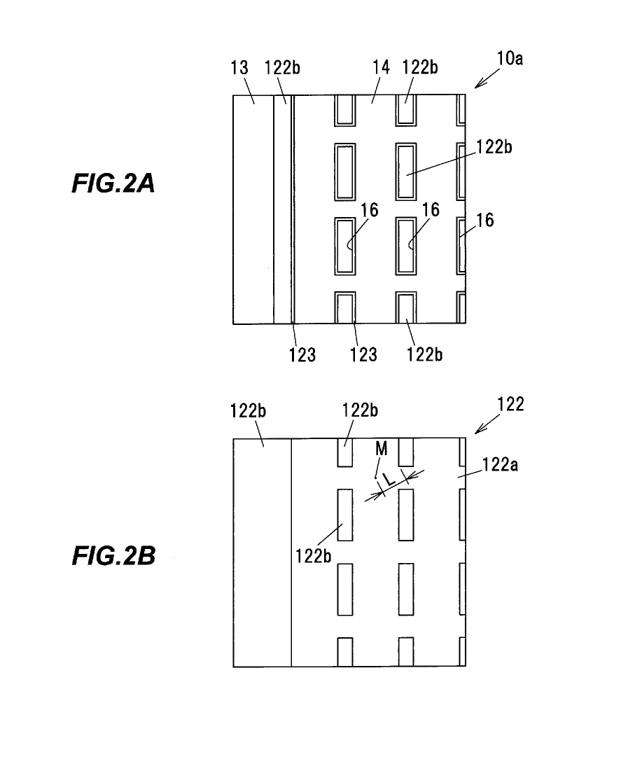

FIG. 2A is a top view showing a modification example of the nitride semiconductor device in the first embodiment. A nitride semiconductor device 10a is different from the nitride semiconductor device 10 in the plane shape of the n-type nitride semiconductor layer 123 and the electrode 14. In the nitride semiconductor device 10a, the uncovered regions 122b are partially formed by the void portion 16 comprising a groove.

FIG. 2B is a plan view showing the covered region 122a and the uncovered regions 122b in the p-type nitride semiconductor layer 122 of the nitride semiconductor device 10a. A point M in FIG. 2B is one of the farthest points in the covered region 122a from the uncovered region(s) 122b, and is the most hydrogen-remaining point after heat treatment. In addition, the distance L in FIG. 2B represents the shortest distance from the point M to the uncovered region(s) 122b, and the distance L is not greater than 50 μm.

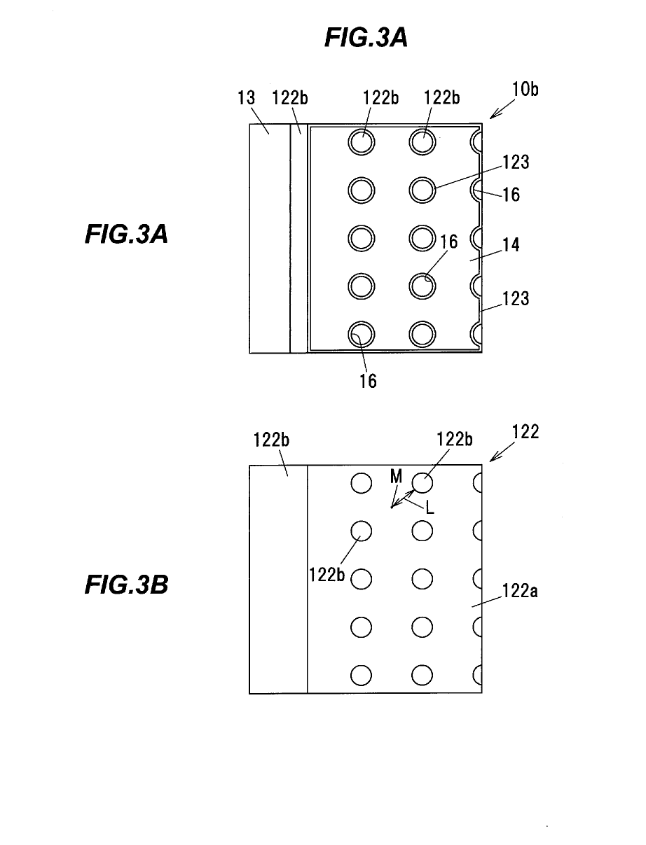

FIG. 3A is a top view showing a nitride semiconductor device 10b which is another modification example of the nitride semiconductor device 10. The nitride semiconductor device 10b is different from the nitride semiconductor device 10 in the plane shape of the n-type nitride semiconductor layer 123 and the electrode 14. In the nitride semiconductor device 10b, the uncovered regions 122b are partially formed by the void portion 16 comprising a plurality of circular holes that are arranged linearly.

FIG. 3B is a plan view showing the covered region 122a and the uncovered regions 122b in the p-type nitride semiconductor layer 122 of the nitride semiconductor device 10b. A point M in FIG. 3B is one of the farthest points in the covered region 122a from the uncovered region(s) 122b, and is the most hydrogen-remaining point after heat treatment. In addition, the distance L in FIG. 3B represents the shortest distance from the point M to the uncovered region(s) 122b, and the distance L is not greater than 50 μm.

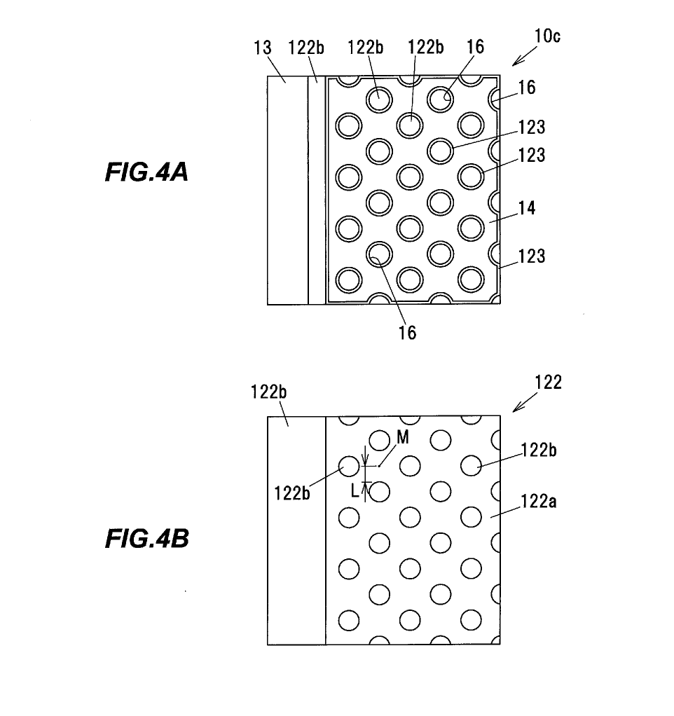

FIG. 4A is a top view showing a nitride semiconductor device 10c which is still another modification example of the nitride semiconductor device 10. The nitride semiconductor device 10c is different from the nitride semiconductor device 10 in the plane shape of the n-type nitride semiconductor layer 123 and the electrode 14. In the nitride semiconductor device 10c, the uncovered regions 122b are partially formed by the void portion 16 comprising circular holes that are arranged in the check pattern.

FIG. 4B is a plan view showing the covered region 122a and the uncovered regions 122b in the p-type nitride semiconductor layer 122 of the nitride semiconductor device 10c. A point M in FIG. 4B is one of the farthest points in the covered region 122a from the uncovered region(s) 122b, and is the most hydrogen-remaining point after heat treatment. In addition, the distance L in FIG. 4B represents the shortest distance from the point M to the uncovered region(s) 122b, and the distance L is not greater than 50 μm.

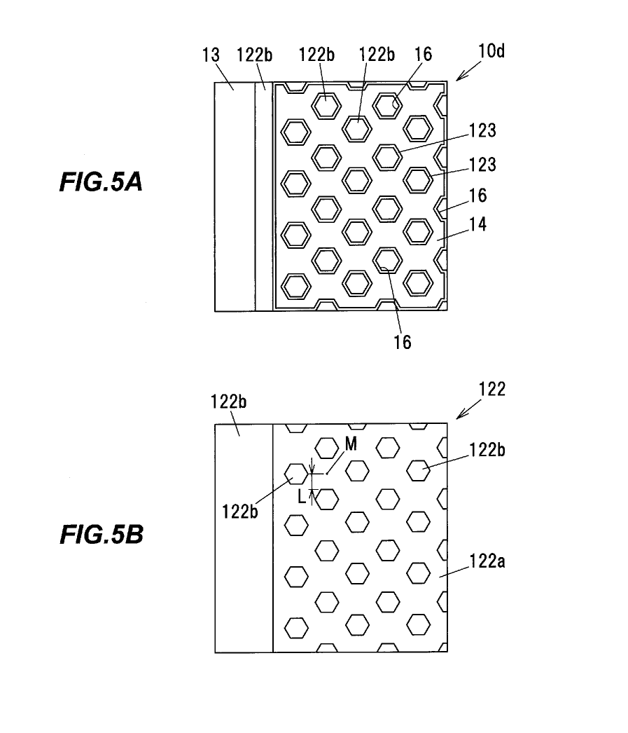

FIG. 5A is a top view showing a nitride semiconductor device 10d which is further modification example of the nitride semiconductor device 10. The nitride semiconductor device 10d is different from the nitride semiconductor device 10 in the plane shape of the n-type nitride semiconductor layer 123 and the electrode 14. In the nitride semiconductor device 10d, the uncovered regions 122b are partially formed by the void portion 16 comprising hexagonal holes that are arranged in the check pattern.

When the n-type nitride semiconductor layer 123 is made of gallium nitride, and a crystal plane at a surface of the n-type nitride semiconductor layer 123 is c-plane, i.e. (0001) plane, as long as the plane shape of the void portion 16 is hexagonal, it is possible to suppress the damage to the crystal by etching because gallium nitride is hexagonal crystal. The etching will be facilitated if the crystal orientation for etching the crystal in hexagonal shape is determined such that side surface(s) of the n-type nitride semiconductor layer 123 is a plane perpendicular to an axis inclined in a c-axis orientation with respect to a (10-10) plane or an axis perpendicular to the (10-10) plane.

FIG. 5B is a plan view showing the covered region 122a and the uncovered regions 122b in the p-type nitride semiconductor layer 122 of the nitride semiconductor device 10d. A point M in FIG. 5B is one of the farthest points in the covered region 122a from the uncovered region(s) 122b, and is the most hydrogen-remaining point after heat treatment. In addition, the distance L in FIG. 5B represents the shortest distance from the point M to the uncovered region(s) 122b, and the distance L is not greater than 50 μm.

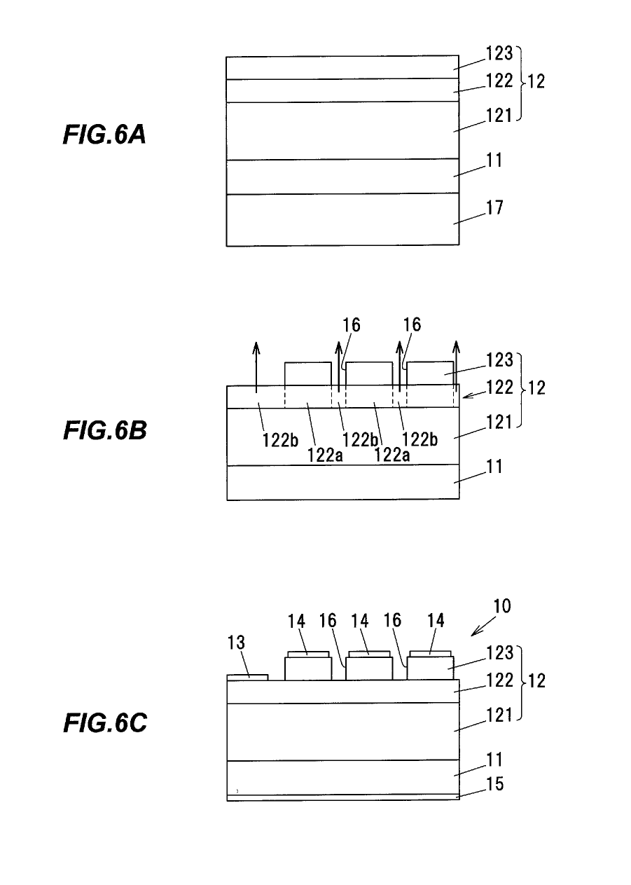

FIGS. 6A to 6C are vertical cross-sectional views showing a process of manufacturing the nitride semiconductor device in the first embodiment.

First, as shown in FIG. 6A, the n-type nitride semiconductor layer 11, the n-type nitride semiconductor layer 121, the p-type nitride semiconductor layer 122, and the n-type nitride semiconductor layer 123 are sequentially formed on a substrate 17 by MOVPE method or HYPE method.

In the case of using e.g. Void Assisted Separation (VAS) method, a sapphire substrate or the like is used as the substrate 17, and peeled off after the n-type nitride semiconductor layer 123 is formed. In the case of using a nitride semiconductor substrate as the substrate 17, the thickness of the substrate 17 is adjusted by polishing after the n-type nitride semiconductor layer 123 is formed, and the substrate 17 is used as a part of the n-type nitride semiconductor layer 11.

Next, as shown in FIG. 6B, for example, the n-type nitride semiconductor layer 123 is partially removed by photolithography and dry etching such that a region for electrically connecting the electrode 13 of the p-type nitride semiconductor layer 122 and a region at the bottom of the void portion 16 are exposed, to form the uncovered regions 122b.

Subsequently, hydrogen in the p-type nitride semiconductor layer 122 is released from the uncovered regions 122b by heat treatment. At this time, the uncovered regions 122b are arranged to meet the above condition, so that it is possible to release hydrogen in the covered region 122a effectively.

Next, as shown in FIG. 6C, the electrode 13, the electrode 14, and the electrode 15 are electrically connected to the p-type nitride semiconductor layer 122, the n-type nitride semiconductor layer 123, and the n-type nitride semiconductor layer 11, respectively.

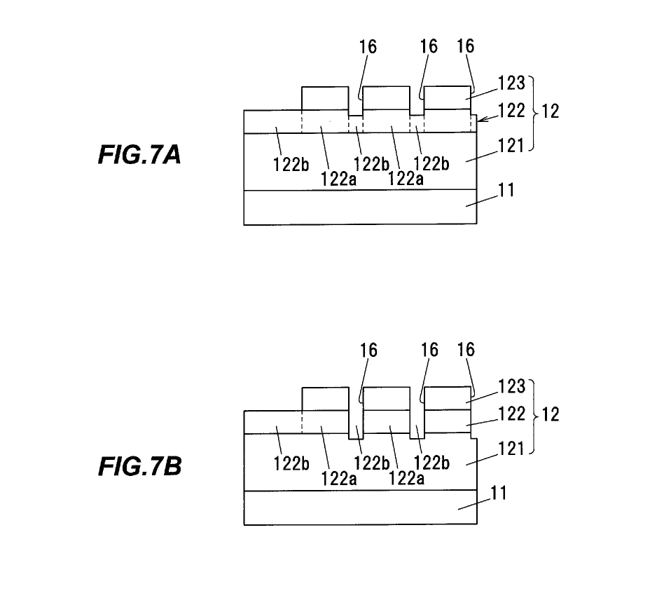

As shown in FIG. 7A, when the n-type nitride semiconductor layer 123 is partially removed, the p-type nitride semiconductor layer 122 may be partially removed such that the bottom of the void portion 16 reaches the inside of the p-type nitride semiconductor layer 122. For this case, the n-type nitride semiconductor layer 123 and the p-type nitride semiconductor layer 122 constitute inner side surfaces of the void portion 16, and an exposed area of the p-type nitride semiconductor layer 122 provided by the void portion 16 is increased, so that it is possible to release hydrogen more effectively.

Alternatively, as shown in FIG. 7B, when the n-type nitride semiconductor layer 123 is partially removed, the p-type nitride semiconductor layer 122 and the n-type nitride semiconductor layer 121 may be partially removed such that the bottom of the void portion 16 reaches the inside of the n-type nitride semiconductor layer 121. For this case, the n-type nitride semiconductor layer 123, the p-type nitride semiconductor layer 122, and the n-type nitride semiconductor layer 121 constitute inner side surface(s) of the void portion 16, and an exposed area of the p-type nitride semiconductor layer 122 provided by the void portion 16 is increased, so that it is possible to release hydrogen even more effectively.

### Second Embodiment

(Nitride Semiconductor Device)

In the second embodiment, the configuration of the emitter electrode is different from that in the first embodiment. The explanation as to the same points as in the first embodiment is omitted or simplified.

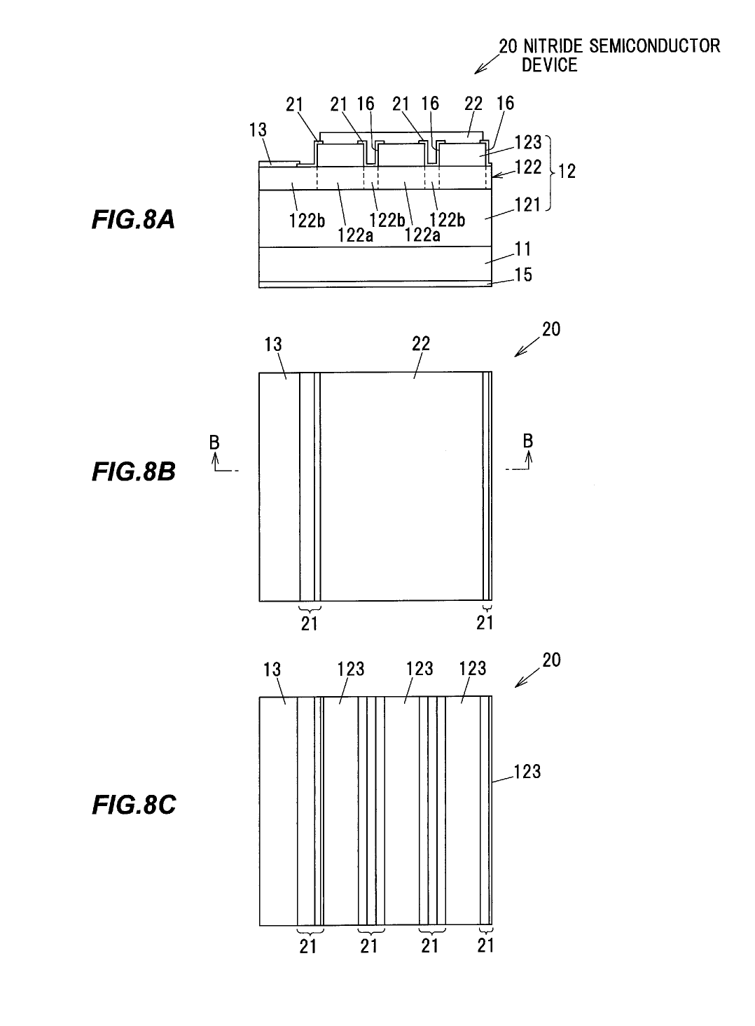

FIGS. 8A and 8B are diagrams showing a nitride semiconductor device in the second embodiment, wherein FIG. 8A is a vertical cross-sectional view thereof, and FIG. 8B is a top view thereof. FIG. 8A is illustrating a cross-sectional view taken along line B-B in FIG. 8B.

A nitride semiconductor device 20 comprises an n-type nitride semiconductor layer 11, an npn junction structure 12 formed by laminating an n-type nitride semiconductor layer 121, a p-type nitride semiconductor layer 122, and an n-type nitride semiconductor layer 123 sequentially in this order on the n-type nitride semiconductor layer 11, an electrode 13 which is a base electrode electrically connected to the p-type nitride semiconductor layer 122, an electrode 22 which is an emitter electrode electrically connected in common to a plurality of portions which are divided by the void portion 16 of the n-type nitride semiconductor layer 123, an electrode 15 which is a collector electrode electrically connected to the n-type nitride semiconductor layer 11, and an insulating film 21 which is formed in the void portion 16 opened at an upper surface of the n-type nitride semiconductor layer 123 and electrically isolates the p-type nitride semiconductor layer 122 from the electrode 22.

FIG. 8C is a top view showing the nitride semiconductor device 20 in which the emitter electrode 22 is not shown. As shown in FIG. 8C, the insulating film 21 is formed to cover at least a portion exposed in the void portion 16 of the p-type nitride semiconductor layer 122. For example, the insulating film 21 is made of an insulating material composed mainly of silicon dioxide.

In the nitride semiconductor device 10 of the first embodiment shown in FIGS. 1A to 1C, the n-type nitride semiconductor layer 123 is divided into a plurality of portions by the void portion 16, and the electrode 14 electrically connected to the n-type nitride semiconductor layer 123 is also divided into a plurality of portions. Thus, when the electrodes are divided into a plurality of portions, the step of connecting the electrodes to each other is complicated, because it is necessary to electrically connect the electrodes such as wire electrodes to respective divided portions.

For example, as in the nitride semiconductor device 10c shown in FIG. 4, when a number of void portions 16 are provided, the step of forming the electrode 14 becomes complicated, because it is necessary to provide the electrode 14 with a complex pattern so as to avoid covering the void portions 16.

On the other hand, in the nitride semiconductor device 20 according to the present embodiment, it is possible to form the single electrode 22 to cover the upper surface of the n-type nitride semiconductor layer 123 entirely, because the p-type nitride semiconductor layer 122 is electrically insulated from the electrode 22 by the insulating film 21. Therefore, the electrode such as the wire electrode to be electrically connected to the electrode 22 may be provided solely, and it is not necessary to provide the electrode 22 with a complex pattern.

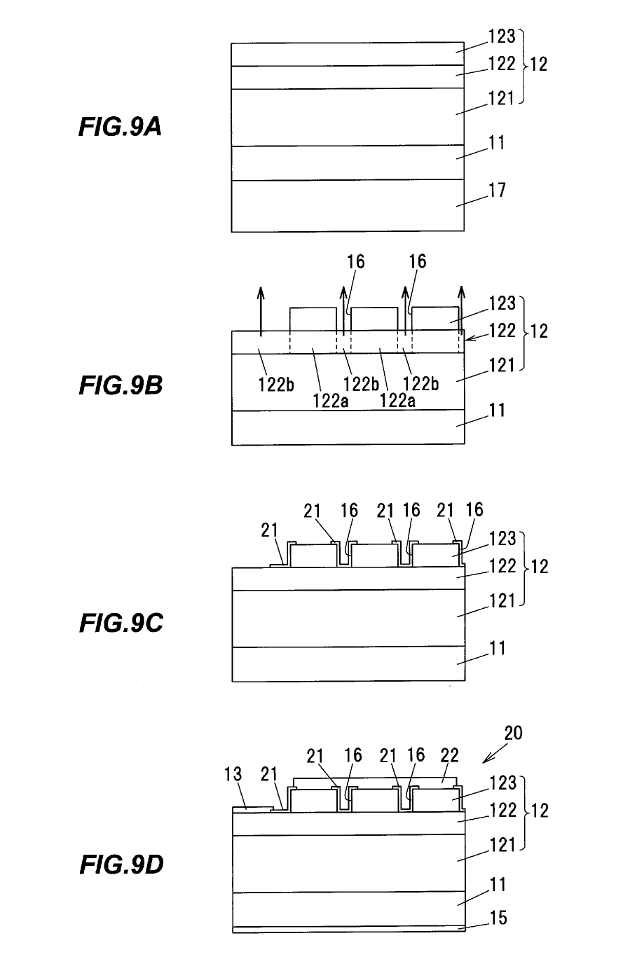

FIGS. 9A to 9D are vertical cross-sectional views showing the process of manufacturing the nitride semiconductor device in the second embodiment.

First, as shown in FIG. 9A, the n-type nitride semiconductor layer 11, the n-type nitride semiconductor layer 121, the p-type nitride semiconductor layer 122, and the n-type nitride semiconductor layer 123 are sequentially formed on the substrate 17 by MOVPE method or HYPE method.

Next, as shown in FIG. 9B, for example, the n-type nitride semiconductor layer 123 is partially removed by photolithography and dry etching such that a region for electrically connecting the electrode 13 of the p-type nitride semiconductor layer 122 and a region at the bottom of the void portion 16 are exposed, to form the uncovered regions 122b.

Subsequently, hydrogen in the p-type nitride semiconductor layer 122 is released from the uncovered regions 122b by heat treatment.

Next, as shown in FIG. 9C, the insulating film 21 is formed to cover at least a portion exposed in the void portion 16 of the p-type nitride semiconductor layer 122.

Next, as shown in FIG. 9D, the electrode 13, the electrode 15, and the electrode 22 are electrically connected to the p-type nitride semiconductor layer 122, the n-type nitride semiconductor layer 11, and the n-type nitride semiconductor layer 123, respectively.

(Effects of the Embodiments)

According to the first and second embodiments described above, it is possible to release hydrogen in the p-type nitride semiconductor layer by heat treatment effectively, because the p-type nitride semiconductor layer 122 has two or more uncovered regions 122b that are uncovered with the n-type nitride semiconductor layer 123. Thus, it is possible to suppress the decrease in electrical conductivity of the p-type nitride semiconductor layer due to hydrogen by activating the acceptors.

In addition, because the uncovered regions 122b are disposed in an arrangement suitable to release hydrogen effectively, it is possible to activate the acceptors more effectively.

### EXAMPLE 1

As Example 1, nitride semiconductor devices 10, 10a, 10b, 10c, and 10d in the first embodiment were prepared and the relationship between the position of the uncovered regions 122b and the residual concentration of hydrogen in the p-type nitride semiconductor layer 122 was examined.

First, the n-type nitride semiconductor layer 11, the n-type nitride semiconductor layer 121, the p-type nitride semiconductor layer 122, and the n-type nitride semiconductor layer 123 were sequentially formed on the substrate 17 by VAS method to provide a layered structure made of a nitride semiconductor.

Here, c-plane sapphire substrate of 6 inches (15.24 cm) was used as the substrate 17. Then, a 400 μm-thick n-type GaN sub-collector layer doped with Si at a concentration of about 5×10¹⁸ cm⁻³, a 10 μm-thick n-type GaN collector layer doped with Si at a concentration of about 5×10¹⁸ cm⁻³, a 0.1 μm-thick p-type GaN base layer doped with Mg, and a 0.2 μm-thick n-type GaN emitter layer doped with Si at a concentration of about 2×10¹⁸ cm⁻³ were formed as the n-type nitride semiconductor layer 11, the n-type nitride semiconductor layer 121, the p-type nitride semiconductor layer 122, and the n-type nitride semiconductor layer 123, respectively.

The n-type nitride semiconductor layer 11, the n-type nitride semiconductor layer 121, the p-type nitride semiconductor layer 122, and the n-type nitride semiconductor layer 123 were formed by HYPE method. The growth pressure was atmospheric pressure, and the deposition temperature was about 1000 degrees Celsius. As source materials, metal source of each element, hydrogen chloride, and ammonia were used, and hydrogen and nitrogen were used as carrier gas. After the growth, the substrate 17 comprising a sapphire substrate was peeled off naturally.

Four layered structures were manufactured by changing only the Mg concentration of the p-type nitride semiconductor layer 122 which is the p-type GaN base layer. The Mg concentration of the p-type nitride semiconductor layer 122 in the four layered structures were about 5×10¹⁸ cm⁻³, about 1×10¹⁹ cm⁻³, about 2×10¹⁹ cm⁻³, and about 5×10¹⁹ cm⁻³, respectively. Hereinafter, the four layered structures with the Mg concentration of the p-type nitride semiconductor layer 122 of about 5×10¹⁸ cm⁻³, about 1×10¹⁹ cm⁻³, about 2×10¹⁹ cm⁻³, and about 5×10¹⁹ cm⁻³, respectively, are called as layered structures A, B, C, and D.

Then, the hydrogen concentration in the center of the p-type nitride semiconductor layer 122 in each of the layered structures A, B, C, and D was measured by Secondary Ion Mass Spectra (SIMS) analysis method. The measured hydrogen concentrations of the layered structures A, B, C, and D were about 2×10¹⁸ cm⁻³, about 5×10¹⁸ cm⁻³, about 1×10¹⁹ cm⁻³, and about 2×10¹⁹ cm⁻³, respectively.

In addition to the layered structures A, B, C and D, a layered structure E including an AlGaN emitter layer as the n-type nitride semiconductor layer 123 was manufactured. The composition of the AlGaN emitter layer was Al_{0.05}Ga_{0.95}N (Al composition was 5%), and the concentration of Si contained in the AlGaN emitter layer was about 2×10¹⁸ cm⁻³. The layers other than n-type nitride semiconductor layer 123 in the layered structure E were the same as those in the layered structures A, B, C, and D.

The hydrogen concentration at the center of the p-type nitride semiconductor layer 122 in the layered structure E was measured by SIMS method, and the measured hydrogen concentration was about 2×10¹⁹ cm⁻³.

In addition, a layered structure F including an InGaN base layer as the p-type nitride semiconductor layer 122 was manufactured. The composition of the InGaN base layer was In_{0.03}Ga_{0.97}N (In composition was 3%), and the concentration of Mg contained in the InGaN base layer was about 5×10¹⁹ cm⁻³. The layers other than the p-type nitride semiconductor layer 122 in the layered structure F were the same as those in the layered structures A, B, C, and D.

The hydrogen concentration at the center of the p-type nitride semiconductor layer 122 in the layered structure F was measured by SIMS method, and the measured hydrogen concentration was about 2×10¹⁸ cm⁻³.

Then, the n-type nitride semiconductor layer 123 in each of the obtained layered structures A, B, C, D, E, and F was processed into the pattern shown in FIG. 1B by Reactive Ion Etching (RIE) with chlorine gas. At this time, the depth of the void portion 16 is varied within the range of 0.2 to 0.4 μm. In some points, the bottom of the void portion 16 reached the inside of the p-type nitride semiconductor layer 122 as shown in FIG. 7A, or the bottom of the void portion 16 reached the inside of the n-type nitride semiconductor layer 121 as shown in FIG. 7B. However, as a result, the influence on the efficiency of hydrogen removal due to the variation in depth of the void portion 16 was not observed.

For each layered structure A, B, C, D, E, and F, the samples in which the n-type nitride semiconductor layer 123 was processed to have the distance L of 25 μm, 35 μm, 50 μm, 60 μm, and 65 μm, respectively, were manufactured. Here, as shown in FIG. 1C, the distance L is the shortest distance from the point M to the uncovered region(s) 122b, and the point M is one of the farthest points from the uncovered region(s) 122b in the covered region 122a.

Next, the samples having distance L of 25 μm, 35 μm, 50 μm, 60 μm, and 65 μm for each of the layered structures A, B, C, D, E, and F were heat-treated at a temperature of 500 degrees Celsius in dry air for 2 hours to release hydrogen.

Next, for each sample, the hydrogen concentration in the p-type nitride semiconductor layer 122 at the point M was measured by SIMS analysis method.

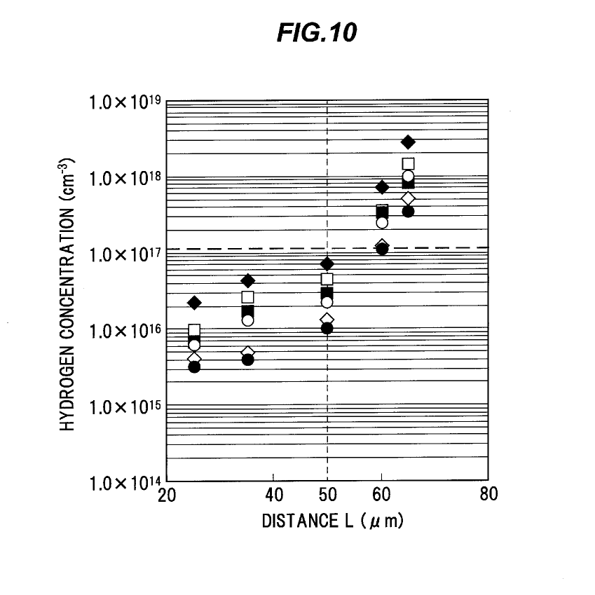

FIG. 10 is a graph showing a relationship between the distance L and the residual hydrogen concentration after heat treatment of each sample. In FIG. 10, the horizontal axis represents the distance L (μm) of each sample, and the vertical axis represents the hydrogen concentration (cm⁻³)in the p-type nitride semiconductor layer 122 at the point M after heat treatment. Plotted points “⋄”, “∘”, “▪”, “□”, “♦”, and “” in FIG. 10 represent the measurements for the layered structures A, B, C, D, E, and F, respectively.

FIG. 10 shows that the hydrogen concentration in the p-type nitride semiconductor layer 122 at the point M after heat treatment is suppressed to 1×10¹⁷ cm⁻³ or less when the distance L is 50 μm or less, in all the layered structures A, B, C, D, E, and F. If the hydrogen concentration in the p-type nitride semiconductor layer 122 is 1×10¹⁷ cm⁻³ or less, the concentration of the acceptor to be inactivated would be also 1×10¹⁷ cm⁻³ or less, so that the p-type nitride semiconductor layer 122 would have a sufficient electrical conductivity. For example, W. Gotz, et al., Appl. Phys. Lett., 67, 2666 (1995) discloses that hydrogen in the p-type nitride semiconductor layer may inhibit the activation of the acceptor but the effect of hydrogen is negligible when the hydrogen concentration is 1×10¹⁷ cm⁻³ or less.

Further, the n-type nitride semiconductor layer 123 in each of the layered structures A, B, C, D, E, and F was processed into a pattern shown in FIGS. 2A to 5A. Then, the same heat treatment was carried out and the hydrogen concentration was measured. The similar relationship between the residual hydrogen concentration after heat treatment and the distance L was confirmed (see FIG. 10). This result shows that the hydrogen concentration of the p-type nitride semiconductor layer 122 at the point M after heat treatment is suppressed to 1×10¹⁷ cm⁻³ or less and the p-type nitride semiconductor layer 122 has a sufficient electrical conductivity, when the distance L is 50 μm or less, regardless of the pattern of the n-type nitride semiconductor layer 123.

Further, the layered structures A, B, C, D, E, and F were manufactured by HYPE method and MOVPE method using GaN free-standing substrate instead of VAS method using a sapphire substrate. Then, the same heat treatment was carried out and the hydrogen concentration was measured. The similar relationship between the residual hydrogen concentration after heat treatment and the distance L was obtained (see FIG. 10).

More specifically, an n-type GaN free-standing substrate of 6 inches was used as the substrate 17, and the n-type nitride semiconductor layer 11, the n-type nitride semiconductor layer 121, the p-type nitride semiconductor layer 122, and the n-type nitride semiconductor layer 123 were sequentially formed on the substrate 17. Here, the manufacturing condition was similar to the manufacturing condition using VAS method except that the n-type nitride semiconductor layer 11 was formed to have a thickness of 10 μm, and the substrate 17 comprising the n-type GaN free-standing substrate was polished after the n-type nitride semiconductor layer 123 is formed to provide the n-type GaN sub-collector in 50 μm thick together with the n-type nitride semiconductor layer 11.

### EXAMPLE 2

As Example 2, a nitride semiconductor device 20 according to the second embodiment was manufactured, so as to confirm that the hydrogen concentration in the p-type nitride semiconductor layer 122 would not be increased by the electrode formation process, in which the upper surface of the entire n-type nitride semiconductor layer 123 is covered with the emitter electrode such as the electrode 22.

As the insulating film 21, the electrode 13 which is a base electrode, the electrode 14 which is an emitter electrode, and the electrode 15 which is a collector electrode, an insulating film composed mainly of SiO₂, a Pd/Au layered film, a Ti/Al layered film, and a Ti/Al layered film were used, respectively.

The insulating film 21 was formed by the following process. First, an insulating film was formed on entire surfaces of the p-type nitride semiconductor layer 122 and the n-type nitride semiconductor layer 123 by sputtering, coating and drying or the like. Thereafter, the insulating film was processed into the pattern shown FIGS. 8A and 8C by photolithography. Here, the insulating film was processed into a pattern in such a manner that the electrode 22 would be electrically insulated from the p-type nitride semiconductor layer 122 and be in ohmic-contact only with the n-type nitride semiconductor layer 123. Then, the residue was removed by buffered hydrofluoric acid, and a Ga-based natural oxide film on the surface was further removed by dilute hydrochloric acid to provide the insulating film 21.

A level difference, step portion or the like existed on the surface of the insulating film 21 thus formed, but the layer breakage etc. of the electrode 22 due to the level difference did not occur, and a flat and smooth surfaced electrode 22 was obtained. In addition, it was confirmed by SIMS analysis that the hydrogen concentration in the p-type nitride semiconductor layer 122 did not increase after the formation of the insulating film 21 and the electrode 22, as compared with the state before the formation thereof.

It should be noted that the present invention is not intended to be limited to the embodiments and Example, and the various changes can be made without departing from the gist of the present invention.

For example, the nitride semiconductor device in the embodiments and the Example may be configured such that the electron affinity of the n-type nitride semiconductor layer 123 is smaller than the electron affinity of the n-type nitride semiconductor layer 121 or the electron affinity of the p-type nitride semiconductor layer 122. For example, such a configuration is disclosed by “L S McCarthy, et al., IEEE Electron Device Lett., 20, 277 (1999)”. In addition, the electron affinity of the p-type nitride semiconductor layer 122 may be larger than the electron affinity of the n-type nitride semiconductor layer 121. For example, such a configuration is disclosed by “Z. Lochner, et al., Appl. Phys. Lett., 99, 193501 (2011)”.

Although the invention has been described with respect to the specific embodiment for complete and clear disclosure, the appended claims are not to be therefore limited but are to be construed as embodying all modifications and alternative constructions that may occur to one skilled in the art which fairly fall within the basic teaching herein set forth.

What is claimed is:

1. A nitride semiconductor device, comprising:
a first nitride semiconductor layer; and
an npn junction structure comprising a second nitride semiconductor layer comprising an n-type conductivity, a third nitride semiconductor layer comprising a p-type conductivity, and a fourth nitride semiconductor layer comprising an n-type conductivity layered in this order on the first nitride semiconductor layer,
wherein the third nitride semiconductor layer comprises two or more uncovered regions which are uncovered with the fourth nitride semiconductor layer.

2. The nitride semiconductor device according to claim 1, wherein a shortest distance from an arbitrary point of a covered region which is covered with the fourth nitride semiconductor layer to the uncovered regions in the third nitride semiconductor layer is 50 μm or less.

3. The nitride semiconductor device according to claim 1, wherein at least a portion of the uncovered regions is a region formed by a void portion opened at an upper surface of the fourth nitride semiconductor layer, and the fourth nitride semiconductor layer and the third nitride semiconductor layer constitute an inner side surface of the void portion.

4. The nitride semiconductor device according to claim 3, wherein the fourth nitride semiconductor layer, the third nitride semiconductor layer, and the second nitride semiconductor layer constitute the inner side surface of the void portion.

5. The nitride semiconductor device according to claim 1, wherein at least a portion of the uncovered regions is a region exposed by a void portion opened at an upper surface of the fourth nitride semiconductor layer, the fourth nitride semiconductor layer comprises a plurality of portions divided by the void portion, a single electrode is connected to the plurality of portions in common, and the electrode is electrically insulated from the third nitride semiconductor layer by an insulating film formed inside the void portion.

6. The nitride semiconductor device according to claim 5, wherein the insulating film comprises an insulating material composed mainly of silicon dioxide.

7. The nitride semiconductor device according to claim 1, wherein each of the first nitride semiconductor layer, the second nitride semiconductor layer, the third nitride semiconductor layer, and the fourth nitride semiconductor layer comprises a nitride semiconductor film formed by Material-Organic Vapor Phase Epitaxy or Hydride Vapor Phase Epitaxy.
